(19) United States
(12) Patent Application Publication
(10) Pub. No.: US 2026/0255807 A1
(43) Pub. Date: Aug. 27, 2026

(54) DISPLAY PANEL AND ELECTRONIC DEVICE INCLUDING THE SAME

(71) Applicant: SAMSUNG DISPLAY CO., LTD., YONGIN-SI (KR)

(72) Inventor: HYUNEOK SHIN, Yongin-si (KR)

(21) Appl. No.: 19/411,850

(22) Filed: Dec. 8, 2025

(30) Foreign Application Priority Data
Feb. 24, 2025 (KR) 10-2025-0023775

(51) Int. Cl. H10K 59/122; H10K 59/131

(52) U.S. Cl. CPC H10K 59/122; H10K 59/131

(57) ABSTRACT

A display panel that includes a base layer on which a plurality of pixel areas and a non-pixel area surrounding the plurality of pixel areas are defined, a circuit element layer disposed on the base layer, and a display element layer disposed on the circuit element layer. The display element layer includes a plurality of light-emitting elements, each having a first electrode, a functional layer, and a second electrode sequentially stacked on each other, a pixel defining layer overlapping the non-pixel area and defining pixel openings to expose at least a portion of a top surface of the first electrode and to respectively correspond to the pixel areas, a metal line disposed on the pixel defining layer and defining metal openings that respectively overlap the pixel openings in plan view, and a cutout portion connecting two adjacent ones of the metal openings.

### CROSS-REFERENCE TO RELATED APPLICATIONS

This . application claims priority under 35 U.S.C. § 119 to and benefits from Korean Patent Application No. 10-2025-0023775 filed on Feb. 24, 2025 in the Korean Intellectual Property Office, the entire contents of which is incorporated by reference herein.

### TECHNICAL FIELD

The disclosure relates to a display panel in which luminance is improved and color mixing is prevented, and an electronic device including the same.

### DISCUSSION OF THE RELATED ART

Electronic devices such as smartphones, tablets, digital cameras, laptop computers, navigation devices, and televisions provide images to users by including display panels.

Display panels divide images into pixels, and the pixels include red pixels, green pixels, and blue pixels to display color. Each of the pixels includes an emission layer to produce the corresponding color in each pixel. Generally, deposition methods using shadow masks have been used to deposit the emission layers. However, since defects such as mask sagging may occur, a process has been developed in which the emission layer and other organic layers may be commonly (or blanket) deposited via an open mask.

However, when organic layers are commonly deposited, lateral leakage current may occur due to the organic layers that are commonly deposited between adjacent pixels, resulting in color mixing and luminance defects between the adjacent pixels.

### SUMMARY

Embodiments of the disclosure provide a display panel in which color mixing between adjacent pixels may be prevented and luminance degradation may be prevented in a display device produced by common deposition of organic layers that include the emission layer, while enhancing driving reliability of elements, and preventing lateral leakage current from occurring between adjacent pixels, and an electronic device including the same.

An embodiment of the disclosure provides a display panel including a base layer on which a plurality of pixel areas and a non-pixel area surrounding the plurality of pixel areas are defined, a circuit element layer disposed on the base layer, and a display element layer disposed on the circuit element layer. The display element layer includes a plurality of light-emitting elements, each having a first electrode, a functional layer, and a second electrode sequentially stacked on each other. The display element layer also includes a pixel defining layer overlapping the non-pixel area and defining a plurality of pixel openings. The plurality of pixel openings are configured to expose at least a portion of a top surface of the first electrode and to respectively correspond to the plurality of pixel areas. The display element layer also includes a metal line disposed on the pixel defining layer and defining a plurality of metal openings. The plurality of metal openings respectively overlap of the plurality of pixel openings in plan view. The display element layer also includes a cutout portion configured to connect two adjacent metal openings of the plurality of metal openings.

In an embodiment, the non-pixel area may include a first area on which the metal line is disposed and a second area in which the cutout portion is defined. At least a portion of the second electrode overlapping the first area may be disconnected, and the second electrode overlapping the second area may be electrically connected.

In an embodiment, the plurality of pixel areas may include a first pixel area and a second pixel area adjacent to the first pixel area in a first direction. The metal line may be disposed between the first pixel area and the second pixel area.

In an embodiment, the metal line may include a first metal line extending in the first direction and a second metal line extending in a second direction intersecting the first direction in plan view. The first metal line and the second metal line may be connected to each other in plan view to form a single, uninterrupted structure.

In an embodiment, the cutout portion may include a first cutout portion defined in the first metal line and a second cutout portion defined in the second metal line. The first cutout portion may be configured to connect two adjacent metal openings in the second direction to each other, and the second cutout portion may be configured to connect two adjacent metal openings in the first direction to each other.

In an embodiment, the plurality of light-emitting elements may include a first light-emitting element corresponding to the first pixel area and in which a (1-1)-th electrode, a first functional layer, and a (2-1)-th electrode sequentially stacked on each other; and a second light-emitting element corresponding to the second pixel area and in which a (1-2)-th electrode, a second functional layer, and a (2-2)-th electrode sequentially stacked on each other. A portion of the first functional layer and a portion of the second functional layer may be spaced apart from each other in the first direction with the metal line disposed between the portion of the first functional layer and the portion of the second functional layer.

In an embodiment, a portion of the (2-1)-th electrode and a portion of the (2-2)-th electrode may be spaced apart from each other in the first direction with the metal line disposed between the portion of the (2-1)-th electrode and the portion of the (2-2)-th electrode.

In an embodiment, a surface area of each of the plurality of metal openings in plan view may be greater than a surface area of each of the pixel openings in plan view.

In an embodiment, the metal line may be disposed directly on the pixel defining layer.

In an embodiment, the metal line may be disposed on a portion of a top surface of the pixel defining layer in plan view.

In an embodiment, the metal line may include a bottom surface in contact with the pixel defining layer, a top surface facing the bottom surface in a thickness direction, and a side surface surrounding the bottom surface and the top surface. The side surface may be in contact with the functional layer.

In an embodiment, the side surface and the second electrode may be spaced apart from each other in plan view.

In an embodiment, the functional layer may include a first light-emitting stack including a first hole transport region, a first emission layer disposed on the first hole transport region, and a first electron transport region disposed on the first emission layer, a charge generation layer disposed on the first light-emitting stack, and a second light-emitting stack including a second hole transport region, a second emission layer disposed on the second hole transport region, and a second electron transport region disposed on the second emission layer.

In an embodiment of the disclosure, a display panel includes a base layer in which a plurality of pixel areas and a non-pixel area surrounding the plurality of pixel areas are defined, a circuit element layer disposed on the base layer, and a display element layer disposed on the circuit element layer. The display element layer includes a plurality of light-emitting elements, each having a first electrode, a functional layer, and a second electrode sequentially stacked on each other. The display element layer also includes a pixel defining layer overlapping the non-pixel area and defining a plurality of pixel openings. The plurality of pixel openings are configured to expose at least a portion of a top surface of the first electrode and to respectively correspond to the plurality of pixel areas in plan view. The display element layer also includes a low-resistance layer overlapping the non-pixel area and disposed on the pixel defining layer. A side surface of the low-resistance layer is not in contact with the second electrode.

In an embodiment, the low-resistance layer may include aluminum or titanium.

In an embodiment, the display panel may further include an encapsulation layer disposed on the display element layer.

In an embodiment of the disclosure, an electronic device is configured to provide an image. The electronic device includes a display module including a display panel in which a plurality of pixel areas and a non-pixel area surrounding the plurality of pixel areas are defined, and a power module electrically connected to the display module. The display panel includes a plurality of light-emitting elements, each having a first electrode, a functional layer, and a second electrode sequentially stacked on each other. The display panel also includes a pixel defining layer overlapping the non-pixel area and defining a plurality of pixel openings. The plurality of pixel openings are configured to expose at least a portion of a top surface of the first electrode and to respectively correspond to the plurality of pixel areas in plan view. The display panel also includes a metal line disposed on the pixel defining layer and defining a plurality of metal openings. The metal openings respectively overlap the plurality of pixel openings in plan view. The display panel also includes a cutout portion configured to connect two adjacent metal openings of the plurality of metal openings in plan view.

In an embodiment, the plurality of pixel areas may include a first pixel area and a second pixel area adjacent to the first pixel area in a first direction, and the plurality of light-emitting elements that may include a first light-emitting element corresponding to the first pixel area and in which a (1-1)-th electrode, a first functional layer, and a (2-1)-th electrode are sequentially stacked on each other, and a second light-emitting element corresponding to the second pixel area and in which a (1-2)-th electrode, a second functional layer, and a (2-2)-th electrode are sequentially stacked on each other.

In an embodiment, a portion of the first functional layer and a portion of the second functional layer may be spaced apart from each other in the first direction with the metal line disposed between the portion of the first functional layer and the portion of the second functional layer, and a portion of the (2-1)-th electrode and a portion of the (2-2)-th electrode may be spaced apart from each other in the first direction with the metal line disposed between the portion of the (2-1)-th electrode and the portion of the (2-2)-th electrode.

In an embodiment, the metal line may include a first metal line extending in the first direction and a second metal line extending in a second direction intersecting the first direction in plan view, the cutout portion may include a first cutout portion defined in the first metal line and a second cutout portion defined in the second metal line, the first cutout portion may be configured to connect two adjacent metal openings in the second direction to each other; and the second cutout portion may be configured to connect two adjacent metal openings in the first direction to each other.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a block diagram of an electronic device according to an embodiment;

FIG. 2 is a schematic diagram of electronic devices according to various embodiments;

FIG. 3A is a perspective view of an assembled electronic device according to an embodiment of the disclosure;

FIG. 3B is an exploded perspective view of the electronic device according to an embodiment of the disclosure;

FIG. 4A is a perspective view of an assembled electronic device according to an embodiment of the disclosure;

FIG. 4B is an exploded perspective view of the electronic device according to an embodiment of the disclosure;

FIG. 5 is a cross-sectional view of a display module according to an embodiment of the disclosure.

FIG. 6 is an enlarged plan view illustrating a portion of a display panel according to an embodiment of the disclosure;

FIG. 7 is a cross-sectional view illustrating a portion of the display panel according to an embodiment of the disclosure;

FIGS. 8A and 8B are cross-sectional views of light-emitting elements according to an embodiment of disclosure, respectively;

FIG. 9A is an enlarged plan view illustrating a portion of a display panel according to an embodiment of the disclosure;

FIG. 9B is an enlarged plan view illustrating a portion of a display panel according to an embodiment of the disclosure;

FIGS. 10A and 10B are enlarged cross-sectional views illustrating portions of a display panel according to an embodiment of the disclosure;

FIG. 11 is an enlarged cross-sectional view illustrating a portion of a display panel according to an embodiment of the disclosure; and

FIG. 12 is a circuit diagram of a partial area of the display panel according to an embodiment of the disclosure.

### DETAILED DESCRIPTION OF THE EMBODIMENTS

It will be understood that when an element or layer is referred to as being "on", "connected to" or "coupled to" another element or layer, it can be directly on, connected or coupled to the other element or layer or intervening elements or layers may be present. In contrast, when an element is referred to as being "directly on," "directly connected to" or "directly coupled to" another element or layer, there are no intervening elements or layers present. Like numbers refer to like elements throughout. As used herein, the term "and/or" includes any and all combinations of one or more of the associated listed items.

Hereinafter, exemplary embodiments of the disclosure will be described with reference to the accompanying drawings.

In this specification, it will also be understood that when a component (or region, layer, portion, etc.) is referred to as being ‘on’, ‘connected to’, or ‘coupled to’ another component, it can be directly connected/coupled on/to the one component, or an intervening third component may also be present.

Although the terms “first,” “second,” etc. may be used herein to describe various elements, these elements should not be limited by these terms. The terms are used solely for the purpose of distinguishing a component from another. For example, a first element referred to as a first element in an embodiment can be referred to as a second element in an embodiment without departing from the scope of the appended claims. The singular forms include the plural forms as well, unless the context clearly indicates otherwise.

Also, “under”, “below”, “above’, “upper”, and the like are used for explaining relation association of components illustrated in the drawings. The terms may be a relative concept and described based on directions expressed in the drawings.

The meaning of “include” or “comprise” specifies a property, a fixed number, a step, an operation, an element, a component or a combination thereof, but does not exclude other properties, fixed numbers, steps, operations, elements, components or combinations thereof.

In this specification, “directly disposed” may mean that there is no layer, film, region, plate, or the like between a portion of the layer, the layer, the region, the plate, or the like and the other portion. For example, “directly disposed” may mean being disposed without using an additional member such and an adhesion member between two layers or two members.

While each drawing may represent one or more particular embodiments of the present disclosure, drawn to scale, such that the relative lengths, thicknesses, and angles can be inferred therefrom, it is to be understood that the disclosure is not necessarily limited to the relative lengths, thicknesses, and angles shown. Changes to these values may be made within the spirit and scope of the present disclosure, for example, to allow for manufacturing limitations and the like.

According to embodiments of the disclosure, there is provided a design for a display device and an electronic device that includes the same that reduces lateral leakage current and improves color purity and image quality in a display device where functional organic layers FL including the emission layers are deposited using an open mask as opposed to a pattern mask. It is recognized that forming functional layers including the emission layer EML by blanket deposition leads to crosstalk problem caused by lateral leakage current between neighboring pixels. Embodiments of the disclosure address this issue by including metal lines ML in non pixel areas NPXA between sub-pixels. These metal lines ML are formed of a highly conductive material that has a lower resistivity than that of the functional layers FL. By including these metal lines ML, lateral leakage current is drawn into the metal lines ML as opposed to entering the functional layer FL of a neighboring pixel, thereby reducing crosstalk between the pixels and resulting in improved color purity and improved image quality.

Another issue addressed is that in earlier designs, other objects were placed between pixels to electrically separate cathode electrodes CE from each other. However this has resulted in increased contact resistance. Although the metal lines of the embodiments of the present disclosure electrically disconnect a cathode electrode of one pixel from another, the embodiments of the disclosure overcome the contact resistance problem by forming the metal lines ML to be non-continuous by including cutting (or removed) parts CC. This allows portions of the cathode electrodes CE of neighboring pixels to still maintain electrical connection between pixels to improve contact resistance.

Hereinafter, a display device according to an embodiment of the disclosure is described below with reference to the drawings.

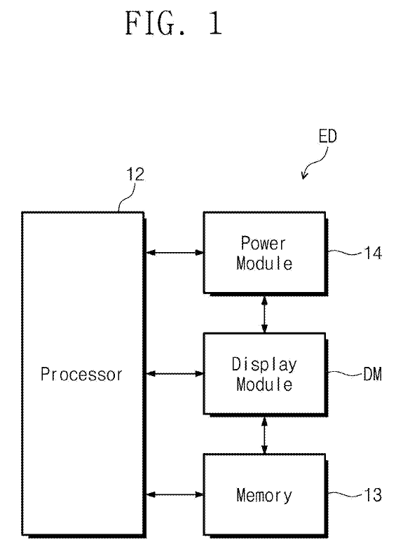

FIG. 1 is a block diagram of an electronic device (“electronic apparatus”) according to an embodiment. Referring to FIG. 1, the electronic apparatus ED may include a display module DM, a processor 12, a memory 13, and a power module 14.

The processor 12 may include at least one of a central processing unit CPU, an application processor AP, a graphic processing unit GPU, a communication processor CP, an image signal processor ISP, or a controlling member.

The memory 13 may store data information desirable for the operation of the processor 12 or the display module DM. When the processor 12 executes an application stored in the memory 13, an image data signal and/or an input control signal may be transmitted to the display module DM, and the display module DM may process the received signal to output image information through a display screen.

The power module 14 may include a power supply module, such as a power adapter or a battery device, and a power conversion module that converts the power supplied by the power supply module to generate the power required for the operation of the electronic apparatus ED.

At least one of the components of the above-described electronic apparatus ED may be included in the display device according to the above-described embodiments. A part of the individual modules functionally included in a single module may be included in the display device, and the other part may be provided separately from the display device. For example, the display device may include the display module DM, and the processor 12, the memory 13, and the power module 14 may be provided in the form of another component in the electronic apparatus ED other than in the display device.

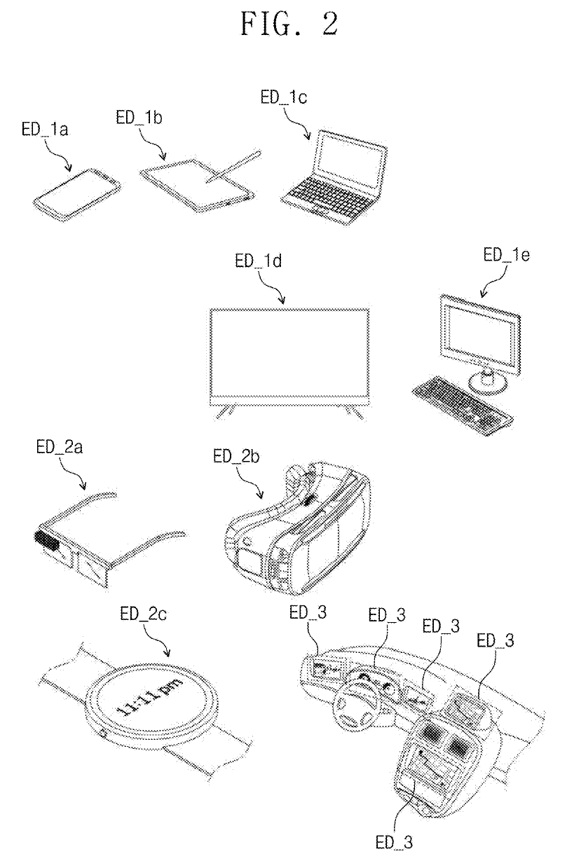

FIG. 2 is a schematic diagram of electronic apparatuses according to various embodiments.

Referring to FIG. 2, various electronic devices to which the display device according to the embodiments is applied may include image display electronic apparatuses such as a smartphone ED_1a, a tablet ED_1b, a laptop ED_1c, a TV ED_1d, and a monitor ED_1e; wearable electronic apparatuses including a display module, such as smart glasses ED_2a, a head-mounted display ED_2b, and a smart watch ED_2c; and vehicle electronic devices ED_3 including display modules, such as a CID (Center Information Display) and a room mirror display, which are disposed on a cluster, center fascia, or dashboard of a vehicle. Also, the above-described apparatuses are exemplified as merely an exemplary embodiment, and thus, the electronic apparatus may be adopted for other electronic apparatuses unless departing from the spirit and scope of the disclosure.

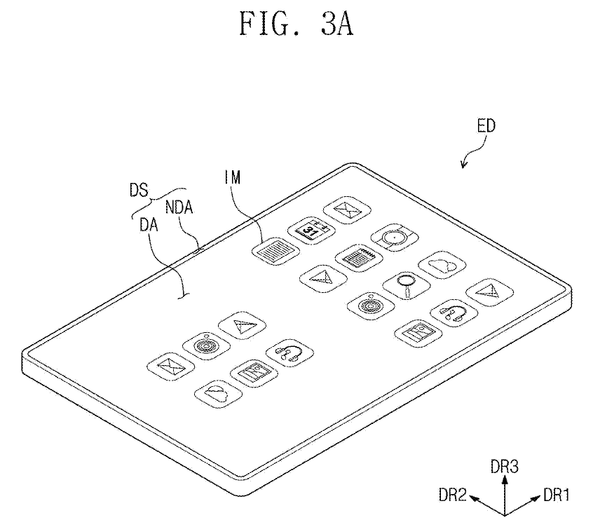

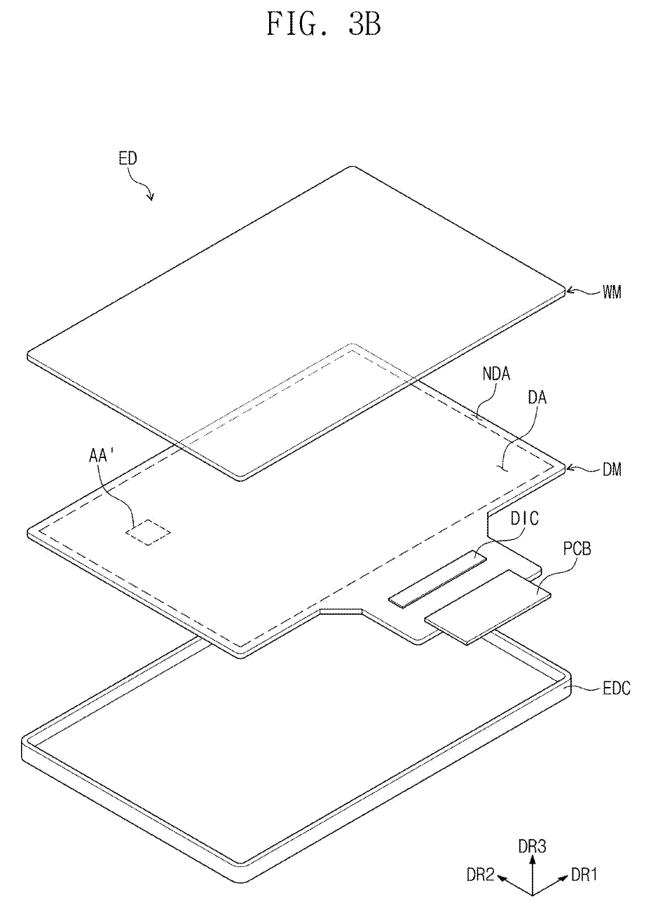

FIG. 3A is a perspective view of an assembled electronic apparatus according to an embodiment of the disclosure. FIG. 3B is an exploded perspective view of the electronic apparatus according to an embodiment of the disclosure. FIGS. 3A and 3B correspond to examples illustrating one of the image display electronic apparatuses such as a smartphone ED_1a, a tablet ED_1b, a laptop ED_1c, a TV ED_1d, and a monitor ED_1e shown in FIG. 2, and are not necessarily limited to the type illustrated therein.

Referring to FIG. 3A, an electronic apparatus ED may be a device that is activated in response to an electrical signal. An electronic apparatus ED may display an image IM and detect an external input. An electronic apparatus ED may be a rigid or a flexible one. "Flexible" refers to a characteristic of being bendable. For example, a flexible electronic apparatus ED may include a curved device, a rollable device, or a foldable device.

An electronic apparatus ED may display an image IM on a display surface DS parallel to each of a first direction DR1 and a second direction DR2 toward a third direction DR3. A display surface DS on which an image IM is displayed may correspond to a front surface of the electronic apparatus ED, and may correspond to a front surface of a window WM. In the specification, the expression that "a region (area) /part corresponds to another region (area) /part" means that the regions/parts overlap but is not necessarily limited to the same surface area. Hereinafter, the display surface, the front surface of the electronic apparatus ED, and the front surface of the window WM will be referred to by the same reference legend DS. The image IM may include a dynamic image and a still image. In FIG. 1, multiple icons are illustrated as an example of the image IM.

In the embodiment, based the direction in which an image IM is displayed, a front surface (or a top surface) and a rear surface (or a bottom surface) of each component are defined. The front and the rear surfaces may oppose each other in a third direction DR3, and a normal direction of each of the front and the rear surfaces may be parallel to the third direction DR3. The front and rear surfaces may have a separation distance therebetween, corresponding to a thickness of the electronic apparatus ED in the third direction DR3. Meanwhile, the directions indicated by the first to third directions DR1, DR2, and DR3 are relative concepts and may be converted into other directions. Hereinafter, the first to third directions may be directions indicated by the first to third directions DR1, DR2, and DR3 and designated by the same reference numerals, respectively. In the specification, "in plan view" may refer to when viewed from above in a direction opposite to the third direction DR3 onto a plane defined by the first direction DR1 and the second direction DR2.

An electronic apparatus ED according to an embodiment of the disclosure may detect an input of a user applied from an exterior. For example, the input of a user includes various types of external inputs such as a portion of the user's body, light, heat, or pressure. The input of the user may be provided in various types, and the electronic apparatus ED may detect the input of the user applied to a side surface or a rear surface of the electronic apparatus ED depending on its structure, and is not necessarily limited to any one embodiment.

As shown in FIG. 3B, the electronic apparatus ED may include the window WM, the display module DM, and an exterior case EDC. In the embodiment, the window WM and the exterior case EDC may be combined to constitute an exterior appearance of the electronic apparatus ED. In the embodiment, the exterior case EDC, the display module DM, and the window WM may be sequentially layered in a third direction DR3.

The window WM may include an optically transparent material. The window WM may include an insulation panel. For example, the window WP may be made of glass, plastic, or a combination thereof.

The front surface of the window WM defines the front surface of the electronic apparatus ED, as described above.

The window WM may include a bezel area and a transmissive area. The transmissive area may be optically transparent. For example, the transmissive area may be an area having a visible light transmittance of about 90% or more.

The bezel area may be an area having lower light transmittance compared to the transmissive area. The bezel area may define a shape of the transmissive area. The bezel area may be adjacent to the transmissive area and may surround the transmissive area. The bezel area may have a color (e.g., predetermined or selectable color). The bezel area may overlap a non-display area NDA of the display module DM. The bezel area may cover the non-display area NDA of the display module DM and may block the non-display area NDA from being visually recognized from an exterior. However, it is only an example, and in the window WM according to an embodiment of the disclosure, the bezel area may be omitted.

The display module DM may include a display area DA and a non-display area NDA. The display area DA may be an area for providing an image IM, and the non-display area NDA may be an area on which a driving circuit or a driving wire is disposed. Multiple light-emitting elements corresponding to respective pixels may be disposed on the display area DA. The non-display region NDA may be adjacent to the display region DA. The non-display area NDA may surround the display area DA. The display module DM may include a driver IC DIC disposed on the non-display area NDA. The display module DM may further include a printed circuit board PCB coupled to the non-display area NDA. The printed circuit board PCB may be electrically connected to pads disposed on the non-display area NDA through an anisotropic conductive adhesive layer.

The driver IC DIC may include driving elements, such as a data driving circuit, for driving pixels of the display module DM. In FIG. 3B, the driver IC DIC is illustrated as being mounted on the display module DM, however, the disclosure is not necessarily limited thereto. For example, the driver IC DIC may be mounted on the printed circuit board PCB.

The exterior case EDC may accommodate the display module DM and may be coupled to the window WM. The exterior case EDC may protect components accommodated in the exterior case EDC, such as the display module DM.

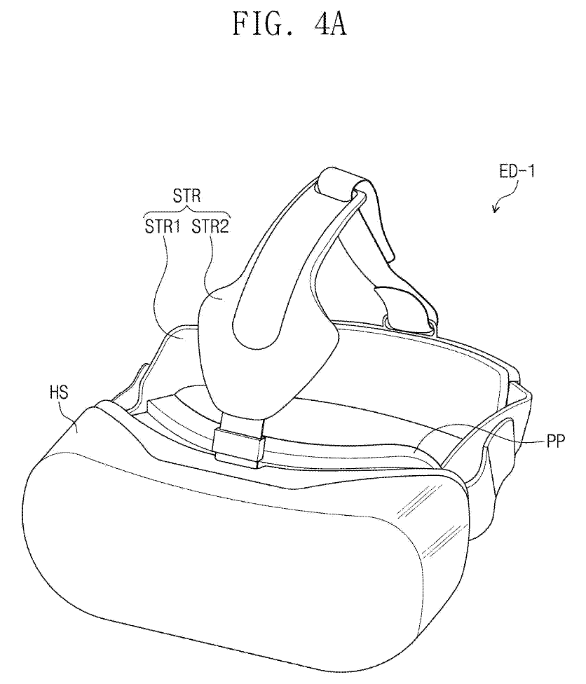

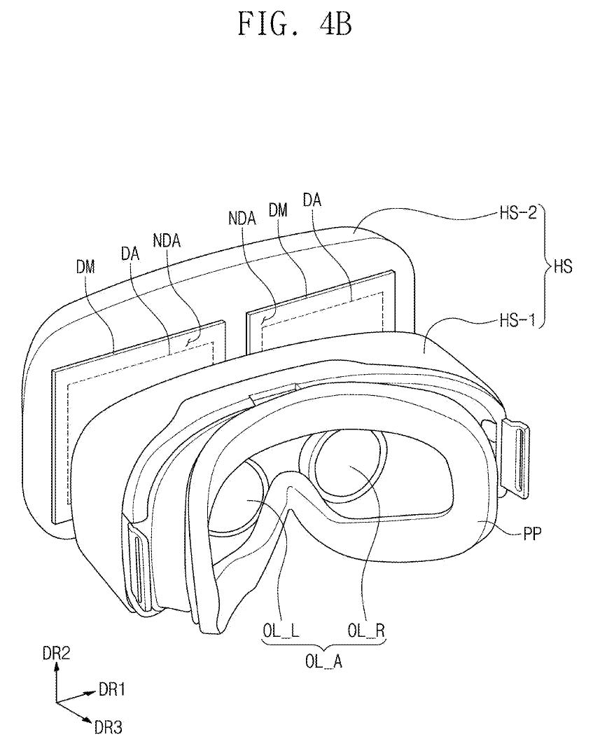

FIG. 4A is a perspective view of an assembled electronic apparatus according to an embodiment of the disclosure. FIG. 4B is an exploded perspective view of the electronic apparatus according to an embodiment of the disclosure. FIGS. 4A and 4B correspond to examples illustrating one of the wearable electronic apparatuses including a display module, such as a smart glasses ED_2a, a head-mounted display ED_2b, and a smart watch ED_2c, shown in FIG. 2, and are not necessarily limited to the type illustrated therein.

An electronic apparatus ED-1 according to an embodiment illustrated in FIGS. 4A and 4B may be a wearable device that is activated in response to an electrical signal. A wearable device may be a device worn on a user's body and may include a head-mounted display (HMD) that implements extended reality (XR). In FIGS. 4A and 4B, the electronic apparatus ED-1 is a head-mounted display as an example, but the disclosure is not necessarily limited thereto.

The electronic apparatus ED-1 according to the embodiment illustrated in FIGS. 4A and 4B may be a display device worn on a user's head. The electronic device ED-1 may provide an image while blocking a user’s actual surrounding view. A user wearing the electronic apparatus ED-1 may be more readily immersed in a virtual reality environment.

The electronic apparatus ED-1 may include a body part HS, a strap part STR, a pad part PP, and a display module DM. Although not illustrated, the electronic apparatus ED-1 may further include various sensors and cameras.

The body part HS may be worn on the user's head. A body part HS may accommodate a display module DM for displaying an image, and an acceleration sensor (not shown). The acceleration sensor may detect a user's movement and may transmit a signal (e.g., predetermined or selectable signal) to the display module DM. Accordingly, the display module DM may provide an image corresponding to a change in the user's gaze. Thus, the user may experience virtual reality similar to actual reality. The structure of the display module DM described in FIG. 3B may be similarly applied to the display module DM. The components of the display module DM included in the electronic apparatus ED-1 according to an embodiment may differ from those illustrated in FIG. 3B, depending on characteristics of the wearable device.

In the body part HS, components having various functions other than those described above may be accommodated. For example, a manipulation part (not shown) that adjusts a volume or screen brightness may be additionally disposed outside the body part HS. The manipulation part may be provided as a physical button or may be provided in the type of a touch sensor. A proximity sensor (not shown) that determines whether the user is wearing the device may be accommodated in the body part HS. An external display panel may be further disposed in a body part HS.

The body part HS may be divided into a body HS-1 and a cover HS-2. In FIG. 4B, a structure in which the body HS-1 and the cover HS-2 are separated is illustrated by way of example, but the disclosure is not necessarily limited thereto. For example, the body HS-1 and the cover HS-2 may be provided as a single, uninterrupted structure and thus might not be separated from each other.

Display modules DM may be disposed between the body HS-1 and the cover HS-2. Each display module DM may provide an image through the display area DA. Each display module DM may include a non-display area NDA surrounding the display area DA. In an embodiment, the non-display area NDA may be placed at a side of the display area DA or may be omitted.

In FIG. 4B, as an example, a left-eye image and a right-eye image are provided by separate display modules DM, but the disclosure is not necessarily limited thereto. For example, the left-eye image and the right-eye image may be displayed through a single display module. The display modules DM may be driven by separate driving parts. However, the disclosure is not necessarily limited thereto, and the display modules DM may also be driven by a single driving part. The display modules DM may generate an image corresponding to input image data.

The strap part STR may be coupled to the body part HS so that the body part HS is readily worn by the user. The strap part STR may include a main strap STR1 and an upper strap STR2.

The main strap STR1 may be worn along a circumference of the user's head. The main strap STR1 may fix the body part HS to the user so that the body part HS is in close contact with the user's head. The upper strap STR2 may connect the body part HS to the main strap STR1 along the top of the user's head. The upper strap STR2 may prevent the body part HS from falling down. The upper strap STR2 may distribute a load on the body part HS to further improve the user's wearing comfort.

When the body part HS may be fixed to a user, the strap part STR may be bent into various shapes in addition to the shape disclosed in FIG. 4A. For example, in an embodiment of the disclosure, the upper strap STR2 may be omitted. In an embodiment of the disclosure, the strap part STR may be modified into various types, such as a helmet coupled to the body part HS or a glasses temple coupled to the body part HS.

The cushion part PP may be disposed between the body part HS and the user's head. The cushion part PP may be made of a material of which a shape is freely deformable. For example, the cushion part PP may be made of a polymer resin (e.g., polyurethane, polycarbonate, polypropylene, and polyethylene) or be made of rubber fluid, an urethane-based material, or sponge made by foaming and molding an acrylic material. However, the material constituting the pad part PP is not necessarily limited thereto.

The cushion part PP may allow the body part HS to be in close contact with the user, thereby improving the user's wearing comfort. The cushion part PP may be detached from the body part HS. In an embodiment of the disclosure, the cushion part PP may be omitted.

An optical system OL_A may be disposed in the body HS-1 of the body part HS. The optical system OL_A may magnify an image provided from display modules DM. Each of the display modules DM may display an image in the third direction DR3 through the display area DA parallel to the first direction DR1 and the second direction DR2 intersecting the first direction DR1. The optical system OL_A may be disposed apart from the display modules DM in the third direction DR3. The optical system OL_A may be disposed between the display modules DM and the user’s eyes. The optical system OL_A may include a right-eye optical system OL_R and a left-eye optical system OL_L. The left eye optical system OL_L may enlarge and provide an image to the user's left pupil, and the right eye optical system OL_R may enlarge and provide an image to the user's right pupil.

The left-eye optical system OL_L and the right-eye optical system OL_R may be disposed apart from each other in the first direction DR1. A distance between the right eye optical system OL_R and the left eye optical system OL_L may be adjusted to correspond to a distance between the user's two eyes. A distance between the optical system OL_A and the display modules DM may be adjustable depending on a user's vision.

The optical system OL_A may be an aspherical lens having a convex shape. For example, the optical system OL_A may be a pancake lens, but is not particularly limited thereto. In this embodiment, an example in which each of the left eye optical system OL_L and the right eye optical system OL_R is provided as a single lens is illustrated, but is not necessarily limited thereto. For instance, each of the left-eye optical system OL_L and the right-eye optical system OL_R may include multiple lenses.

The electronic apparatus ED-1 according to an embodiment illustrated in FIGS. 4A and 4B may further include a window (not shown) disposed on a display module DM. The window (not shown) may be similarly applied as described in FIG. 3B, or may be provided to include a component differ from that illustrated in FIG. 3B, depending on characteristics of the wearable device. The window (not shown) may include a base substrate and a reflection-reducing layer.

The display module DM included in the electronic apparatus ED-1 according to an embodiment may have high-resolution characteristics. For example, the display module DM according to an embodiment may have ultra-high resolution display quality of 3000 ppi or more.

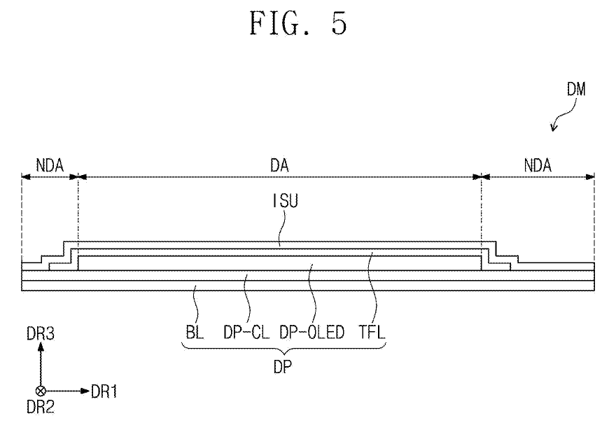

FIG. 5 is a cross-sectional view of the display module according to an embodiment of the disclosure.

Referring to FIG. 5, the display module DM may include a display panel DP and an input sensing unit ISU. The display panel DP may be a component that substantially generates an image IM (see FIG. 3A). The image IM generated by the display panel DP may be visually recognized by a user from an exterior through the display area DA.

The display panel DP may be an emission-type display panel. For example, the embodiment of the disclosure is not necessarily limited to a kind of display panel. For example, the display panel DP may be an organic light-emitting display panel or an inorganic light-emitting display panel. The organic light-emitting display panel may be a display panel including an emission layer containing an organic light-emitting material. The inorganic light-emitting display panel may be a display panel including an emission layer containing quantum dots, quantum rods, or micro LEDs. Hereinafter, the display panel DP is described as an organic light-emitting display panel.

The input sensing unit ISU may be disposed on the display panel DP. The input sensing unit ISU may sense an external input applied from an exterior. The external input may include various types of input provided from an exterior of the electronic apparatus ED (see FIG. 3A). The external input may be provided in various types. For example, the external input may include a touch input caused by a part of the user's body, such as a hand, as well as an input applied when approaching or being located within a distance (e.g., predetermined or selectable distance) from the electronic apparatus ED (see FIG. 3A), such as a hovering input. The external input may have various types such as force, pressure, or light, and is not necessarily limited to an embodiment.

The input sensing unit ISU may be disposed on the display panel DP through a continuous process. In this case, the input sensing unit ISU may be disposed (e.g., “directly disposed”) on the display panel DP. In the specification, the expression that “a configuration B is disposed (e.g., “directly disposed”) on a configuration A” may mean that no third component is disposed between the configuration A and the configuration B. For example, an adhesive layer might not be disposed between the input sensing unit ISU and the display panel DP.

The display panel DP may include a base layer BL, a circuit element layer DP-CL disposed on the base layer BL, a display element layer DP-OLED, and an upper insulating layer TFL.

The base layer BL may provide a base surface on which the circuit element layer DP-CL, the display element layer DP-OLED, and the upper insulating layer TFL are disposed. The base layer BL may be a rigid substrate or a flexible substrate that is bendable, foldable, rollable, or the like. The base layer BL may be a glass substrate, a metal substrate, or a polymer substrate. However, an embodiment of the disclosure is not necessarily limited thereto, and the base layer BL may include an inorganic layer, an organic layer, or a composite material layer.

The base layer BL may have a multilayer structure. For example, the base layer BL may include a first synthetic resin layer, a multilayer or single inorganic layer, and a second synthetic resin layer disposed on the multilayer or single inorganic layer. First and second synthetic resin layers may each include a polyimide-based resin and are not necessarily limited thereto.

The circuit element layer DP-CL may be disposed on the base layer BL. The circuit element layer DP-CL may include multiple insulating layers, multiple conductive layers, and a semiconductor layer. The conductive layers of the circuit element layer DP-CL may provide signal lines or control circuits of pixels.

The display element layer DP-OLED may be disposed on the circuit element layer DP-CL. The display element layer DP-OLED may include light-emitting elements. The display element layer DP-OLED may include, for example, organic light-emitting elements. However, this is merely an example, and the display element layer DP-OLED according to an embodiment of the disclosure may include inorganic light-emitting elements, organic-inorganic light-emitting elements, or a liquid crystal layer.

The upper insulating layer TFL may include a capping layer and a thin film encapsulation layer, which will be described later. The upper insulating layer TFL may include an organic layer and multiple inorganic layers that seal the organic layer.

The upper insulating layer TFL may be disposed on the display element layer DP-OLED and may protect the display element layer DP-OLED from foreign material such as moisture, oxygen, and dust particles. The upper insulating layer TFL may seal the display element layer DP-OLED and block moisture and oxygen from entering the display element layer DP-OLED. The upper insulating layer TFL may include at least one inorganic layer. The upper insulating layer TFL may include an organic layer and multiple inorganic layers that seal the organic layer. The upper insulating layer TFL may include a laminated structure in the order of an inorganic layer, an organic layer, and another inorganic layer.

The input sensing unit ISU may be disposed on the upper insulating layer TFL. The input sensing unit ISU may be disposed on the upper insulating layer TFL through a continuous process. The input sensing unit ISU may be disposed (e.g., “directly disposed”) on the display panel DP. For example, a separate adhesive member might not be disposed between the input sensing unit ISU and the display panel DP. The input sensing unit ISU may be disposed in contact with an inorganic layer, which is positioned at an uppermost part of the upper insulating layer TFL.

Although not separately illustrated, the display module DM according to an embodiment of the disclosure may further include a protection member disposed on a bottom surface of the display panel DP and an anti-reflection member disposed on a top surface of the input sensing unit ISU. The anti-reflection member may reduce the reflectance of external light. The anti-reflection member may be disposed (e.g., “directly disposed”) on the input sensing unit ISU through a continuous process.

The anti-reflection member may include a light-shielding pattern overlapping a reflection structure disposed below the anti-reflection member. The anti-reflection member may further include a color filter. The color filter may be disposed between the light-shielding patterns and may include a first color filter, a second color filter, and a third color filter corresponding to a first color pixel, a second color pixel, and a third color pixel, respectively.

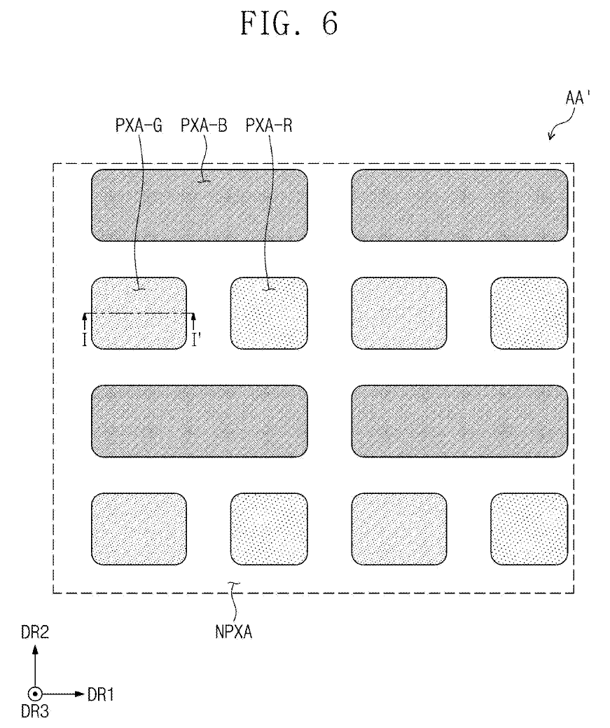

FIG. 6 is an enlarged plan view of a portion of the display panel according to an embodiment of the disclosure. In FIG. 6, an arrangement of multiple pixels is enlarged and illustrated in an AA’ area shown in FIG. 3B.

Referring to FIG. 6, the display area DA in the display panel DP (see FIG. 3B) according to an embodiment may include multiple pixel areas PXA-R, PXA-G, and PXA-B and a non-pixel area NPXA surrounding the pixel areas PXA-R, PXA-G, and PXA-B. The pixel areas PXA-R, PXA-G, and PXA-B may include a first pixel area PXA-R, a second pixel area PXA-G, and a third pixel area PXA-B. Each of the first, second, and third pixel areas PXA-R, PXA-G, and PXA-B may display light of different wavelengths. The first pixel area PXA-R may display first light of a red wavelength, the second pixel area PXA-G may display second light of a green wavelength, and the third pixel area PXA-B may display third light of a blue wavelength.

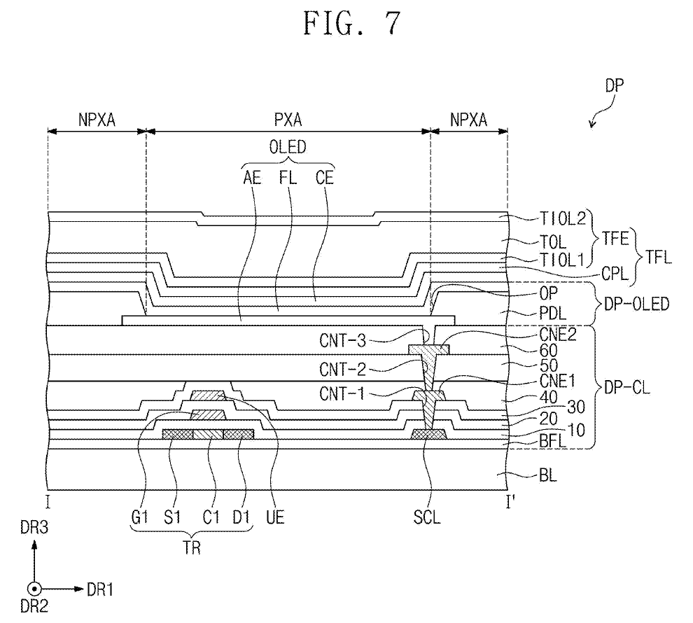

Each of the pixel areas PXA-R, PXA-G, and PXA-B may be an area defined by a pixel defining layer PDL (see FIG. 7). The non-pixel area NPXA may be an area between adjacent pixel areas PXA-R, PXA-G, and PXA-B, and may correspond to the pixel defining layer PDL (see FIG. 7). In the specification, each of the pixel areas PXA-R, PXA-G, and PXA-B may correspond to a pixel. The pixel areas PXA-R, PXA-G, and PXA-B may be divided to correspond to multiple pixel openings (or apertures) OP defined in the pixel defining layer PDL (see FIG. 7).

As shown in FIG. 6, the first pixel area PXA-R and the second pixel area PXA-G may provide a first pixel group arranged in a first direction DR1, and the third pixel area PXA-B may provide a second pixel group arranged in the first direction DR1. The first pixel group, which consists of the first and second pixel areas, and the second pixel group, which consists of the third pixel area, may be spaced apart from each other in a second direction DR2. The first and second pixel groups may be alternately arranged in the second direction DR2.

The pixel areas PXA-R, PXA-G, and PXA-B may have different areas depending on the wavelength of the emitted light. For example, as shown in FIG. 6, the third pixel area PXA-B, which emits the third light, may have the largest surface area, and the first pixel area PXA-R, which emits the first light, may have the smallest surface area. However, the embodiment is not necessarily limited thereto, and the pixel areas PXA-R, PXA-G, and PXA-B may have the same area, or may be defined to have different area ratios than those shown in FIG. 6. The pixel areas PXA-R, PXA-G, and PXA-B may emit light in colors other than the aforementioned red, green, and blue wavelengths.

Each of the pixel areas PXA-R, PXA-G, and PXA-B may have a rectangular shape with rounded corners in plan view. In an embodiment, each of the second pixel area PXA-G and the third pixel area PXA-B may have a rectangular shape with rounded corners, having a long side extended in the first direction DR1 and a short side extended in the second direction DR2. In an embodiment, the first pixel area PXA-R may have a rectangular shape with rounded corners, having a long side extended in the second direction DR2 and a short side extended in the first direction DR1. However, the shapes of the pixel areas PXA-R, PXA-G, and PXA-B are not necessarily limited thereto.

FIG. 7 is a cross-sectional view of a portion of the display panel included in the display module according to an embodiment of the disclosure. FIG. 7 illustrates a cross section taken along a cut line I-I’ in FIG. 6. In FIG. 7, a pixel included in a display panel according to an embodiment is illustrated as an example with light-emitting elements and transistors included in the pixel.

Referring to FIG. 7, in the display panel DP according to an embodiment, a circuit element layer DP-CL, a display element layer DP-OLED, and an upper insulating layer TFL may be sequentially disposed on the base layer BL.

The circuit element layer DP-CL may include at least one insulating layer and a circuit element. The circuit element may include a signal line, a driving circuit of a pixel, and the like. The circuit element layer DP-CL may be generated through an insulating layer, semiconductor layer, and conductive layer formation process by coating or deposition and a patterning process of those layers by a photolithography process.

A buffer layer BFL may include at least one inorganic layer laminated therein. A semiconductor pattern may be disposed on the buffer layer BFL. The buffer layer BFL improve bonding force between the base layer BL and the semiconductor pattern.

The semiconductor pattern may include polysilicon. However, the embodiment of the disclosure is not necessarily limited thereto. For example, the semiconductor pattern may include amorphous silicon or metal oxide. In FIG. 7, a portion of a semiconductor pattern is illustrated, and additional semiconductor patterns may be disposed in other areas of a pixel in plan view. The semiconductor pattern may be arranged in a specific arrangement over the pixels.

The semiconductor pattern may have different electrical characteristics depending on whether it is doped. The semiconductor pattern may include a first region C1 having a low doping concentration and conductivity, and second regions S1 and D1 having higher doping concentrations and conductivities. A second region S1 may be disposed on a side of the first region C1, and another second region D1 may be disposed on another side of the first region C1. The second regions S1 and D1 may be doped with an N-type dopant or a P-type dopant. A P-type transistor may include doped regions doped with a P-type dopant. The first region C1 may be a non-doped region, or may be doped at a concentration lower than the second regions S1 and D1.

The second regions S1 and D1 may substantially serve as electrodes or signal lines. A second region S1 may correspond to a source of a transistor, and another second region D1 may correspond to a drain. FIG. 7 illustrates a portion of a connection signal line SCL provided from the semiconductor pattern. Although not illustrated, the connection signal line SCL may be connected to a drain of a transistor TR in plan view.

A first insulating layer 10 may be disposed on the buffer layer BFL. The first insulating layer 10 may commonly overlap multiple pixels disposed in the display area DA and may cover the semiconductor pattern. The first insulating layer 10 may be an inorganic layer and/or an organic layer, and may have a single-layer or multilayer structure. The first insulating layer 10 may include at least one of aluminum oxide, titanium oxide, silicon oxide, silicon oxynitride, zirconium oxide, and hafnium oxide. The insulation layer of the circuit element layer DP-CL, which will be described later, as well as the first insulation layer 10 may be an inorganic layer and/or an organic layer and may have a single-layered or a multi-layered structure.

The gate G1 may be disposed on the first insulating layer 10. The gate G1 may be a portion of a metal pattern. The gate G1 may overlap the first area C1. During a process of doping the semiconductor pattern, the gate G1 may function as a mask.

A second insulating layer 20 may be disposed on the first insulating layer 10 and may cover a gate G1. The second insulating layer 20 may commonly overlap the pixels. An upper electrode UE may be disposed on the second insulating layer 20. The upper electrode UE may overlap the gate G1. The upper electrode UE may include a multilayer metal layer. In an embodiment of the disclosure, the upper electrode UE may be omitted.

A third insulating layer 30 may be disposed on a second insulating layer 20 and may cover an upper electrode UE. A first connection electrode CNE1 may be disposed on the third insulating layer 30. The first connection electrode CNE1 may be connected to a connection signal line SCL through a contact hole CNT-1 that penetrates through the first to third insulating layers 10 to 30.

A fourth insulating layer 40 may be disposed on the third insulating layer 30, and a fifth insulating layer 50 may be disposed on the fourth insulating layer 40. The fifth insulating layer 50 may be an organic layer. A second connection electrode CNE2 may be disposed on the fifth insulating layer 50. The second connection electrode CNE2 may be connected to the first connection electrode CNE1 through a contact hole CNT-2 penetrating the fourth insulating layer 40 and the fifth insulating layer 50. A sixth insulating layer 60 may be disposed on the fifth insulating layer 50 and may cover the second connection electrode CNE2. The sixth insulating layer 60 may be an organic layer.

The light-emitting element OLED may be disposed on the sixth insulating layer 60. The light-emitting element OLED may include a first electrode AE, a functional layer FL, and a second electrode CE, which are sequentially laminated. The first electrode AE may be disposed on the sixth insulating layer 60. The first electrode AE may be connected to the second connection electrode CNE2 through a contact hole CNT-3 penetrating the sixth insulating layer 60.

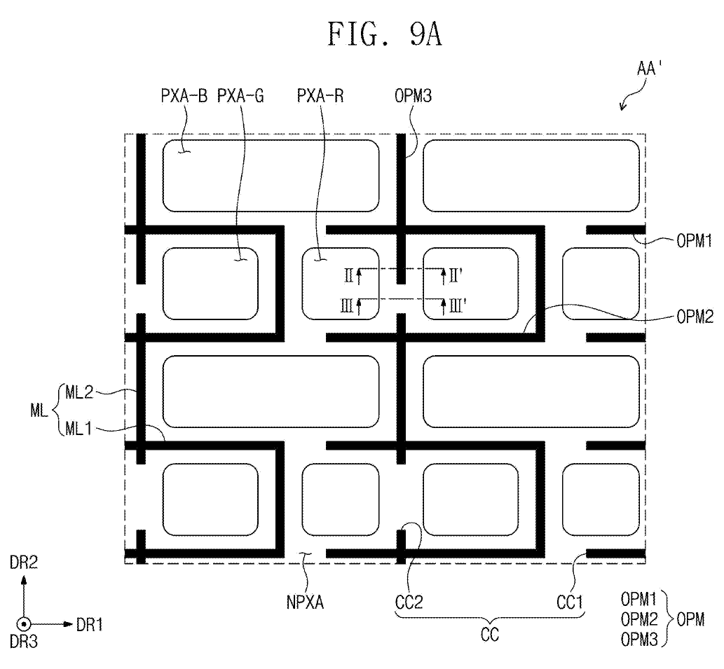

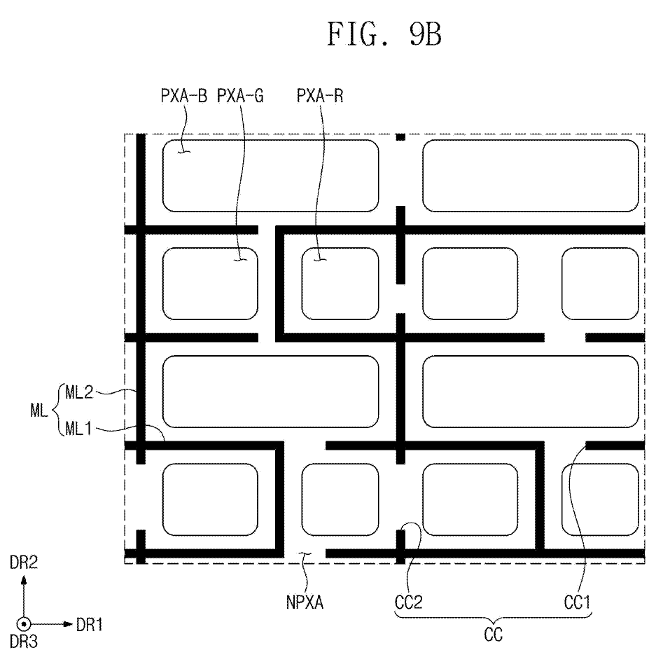

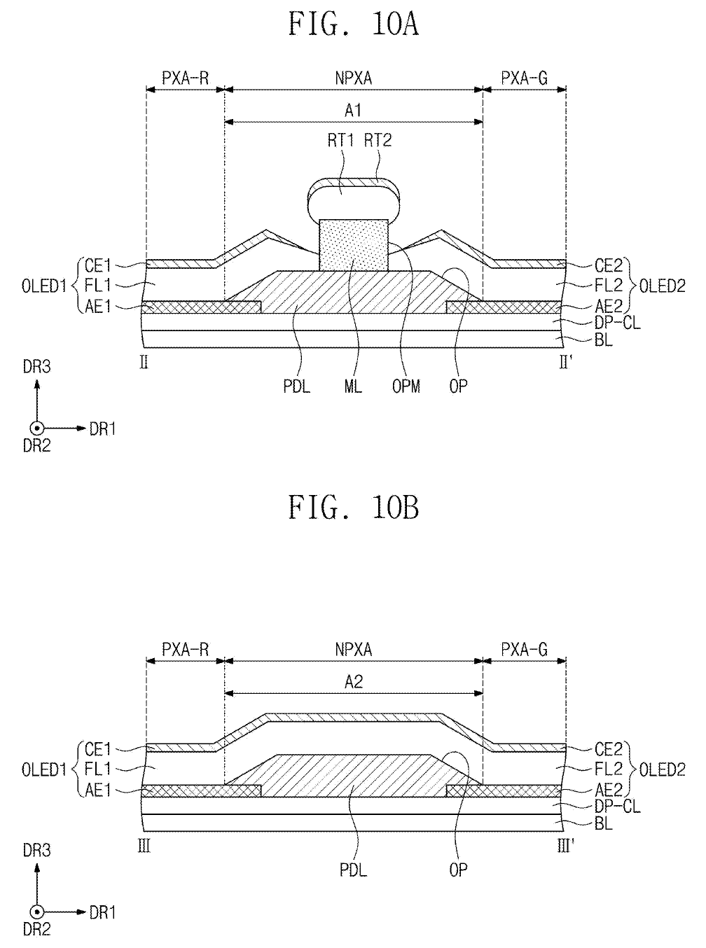

A pixel opening OP may be defined in a pixel defining layer PDL, and the pixel defining layer PDL may expose at least a portion of the first electrode AE. The pixel defining layer PDL may be an organic layer. In the embodiment, a pixel area PXA is defined to correspond to a partial area of the first electrode AE, which is exposed by the pixel opening OP. A metal line ML (see FIG. 10A) may be disposed on the pixel defining layer PDL. A detailed description of the metal line ML is provided below with reference to FIG. 9A and subsequent figures.

The functional layer FL may be disposed in the pixel opening OP, and the second electrode CE may be disposed on the functional layer FL. The functional layer FL and the second electrode CE may be commonly disposed in the pixel area PXA and a non-pixel area NPXA. For example, as opposed to what is shown, the functional layer FL may be patterned through a mask and separately provided in each pixel.

The upper insulating layer TFL may be disposed on the display element layer DP-OLED and may include multiple thin films. According to an embodiment, the upper insulating layer TFL may include a capping layer CPL and an encapsulation layer TFE disposed on the capping layer CPL. The capping layer CPL may be disposed on and in contact with the second electrode CE. The capping layer CPL may include an organic material.

The encapsulation layer TFE may include a first inorganic encapsulation layer TIOL1, an organic encapsulation layer TOL disposed on the first inorganic encapsulation layer TIOL1, and a second inorganic encapsulation layer TIOL2 disposed on the organic encapsulation layer TOL. The first and second inorganic encapsulation layers TIOL1 and TIOL2 may protect the display element layer DP-OLED from moisture and oxygen, and the organic encapsulation layer TOL may protect the display element layer DP-OLED from foreign material such as dust particles.

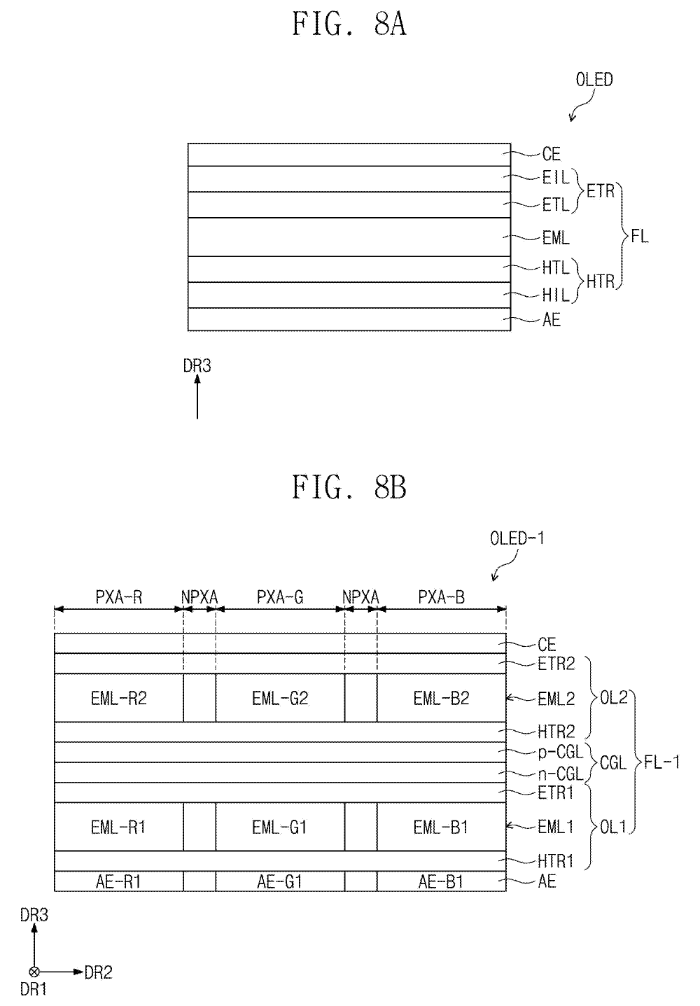

FIGS. 8A and 8B are cross-sectional views showing light-emitting elements according to an embodiment. The light-emitting element OLED of FIG. 7 may have the configuration of the light-emitting element according to an embodiment shown in FIGS. 8A or 8B .

Referring to FIG. 8A, the light-emitting element OLED according to an embodiment may include a first electrode AE, a functional layer FL, and a second electrode CE. The functional layer FL may include a hole transport region HTR, an emission layer EML, and an electron transport region ETR. The light-emitting element OLED according to an embodiment may include a single light-emitting structure in which the hole transport region HTR, the emission layer EML, and the electron transport region ETR are laminated. For example, each functional layer FL shown in FIG. 6 may include a single light-emitting structure composed of a lamination of the hole transport region HTR, the emission layer EML, and the electron transport region ETR.

In the light-emitting element OLED, the first electrode AE may be a transparent electrode, a semi-transparent electrode, or a reflective electrode. The first electrode AE may be made of a metal material, a metal alloy, or a conductive compound. The first electrode AE may include at least one selected from Ag, Mg, Cu, Al, Pt, Pd, Au, Ni, Nd, Ir, Cr, Li, Ca, LiF, Mo, Ti, W, In, Sn, and Zn; a compound selected from two or more of them; a mixture selected from two or more of them; or an oxide thereof.

When the first electrode AE is the transmissive electrode, the first electrode AE may include transparent metal oxide, for example, indium tin oxide (ITO), indium zinc oxide (IZO), zinc oxide (ZnO), or indium tin zinc oxide (ITZO). When the first electrode AE is the transflective electrode or the reflective electrode, the first electrode AE may include Ag, Mg, Cu, Al, Pt, Pd, Au, Ni, Nd, Ir, Cr, Li, Ca, LiF/Ca (laminated structure of LiF and Ca), LiF/Al (laminated structure of LiF and Al), Mo, Ti, W, or a compound or mixture thereof (for example, a mixture of Ag and Mg). For example, the first electrode AE may have a multi-layer structure including a reflective layer or a semi-transmissive layer made of the above-described materials, and a transparent conductive layer made of ITO (indium tin oxide), IZO (indium zinc oxide), ZnO (zinc oxide), ITZO (indium tin zinc oxide), or the like. For example, the first electrode AE may have a three-layer structure of ITO/Ag/ITO, but is not necessarily limited thereto. This embodiment is not necessarily limited thereto, and the first electrode AE may include the above-described metal materials, a combination of two or more metal materials of the above-described metal materials, or oxide of the above-described metal materials.

The second electrode CE may be a transmissive electrode, a semi-transmissive electrode, or a reflective electrode. When the second electrode CE is the transmissive electrode, the second electrode CE may be made of metal oxide, for example, indium tin oxide (ITO), indium zinc oxide (IZO), zinc oxide (ZnO), indium tin zinc oxide (ITZO), or a combination thereof.

When the second electrode CE is a semi-transmissive electrode or a reflective electrode, it may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, or MgYb). For example, the second electrode CE may have a structure of multiple layers including a reflective layer or transflective layer and a transparent conductive layer made of indium tin oxide (ITO), indium zinc oxide (IZO), zinc oxide (ZnO), or indium tin zinc oxide (ITZO). For example, the second electrode CE may include the above-described metal materials, a combination of two or more metal materials of the above-described metal materials, or oxide of the above-described metal materials.

The emission layer EML may be a layer including a light-emitting material. The emission layer EML may have a single layer of a single material, a single layer of different materials, or a multilayer structure of different materials. The emission layer may include a fluorescent or phosphorescent material. In an embodiment, the emission layer EML of the light-emitting element OLED may include a light-emitting material such as an organic light-emitting material, an organometallic complex, or a quantum dot.

In FIG. 8A, the light-emitting element OLED is illustrated as including an emission layer EML, but it may further include an auxiliary emission layer that enhances luminous efficiency in addition to a main emission layer that emits light of a color (e.g., predetermined or selectable color). In an embodiment, the emission layer EML may have a laminated structure of multiple sub emission layers having different light-emitting material compositions.

The light-emitting element OLED may include a hole transport region HTR disposed between the first electrode AE and the emission layer EML. The hole transport region HTR may include at least one of a hole injection layer HIL, a hole transport layer HTL, an emission auxiliary layer, and an electron blocking layer. For example, the hole transport region HTR may include a hole injection layer HIL and a hole transport layer HTL sequentially laminated on the first electrode AE.

The light-emitting element OLED may include an electron transport region ETR disposed between the emission layer EML and the second electrode CE. The electron transport region ETR may include at least one of an electron blocking layer, an electron transport layer ETL, and an electron injection layer EIL. For example, the electron transport region ETR may include an electron transport layer ETL and an electron injection layer EIL disposed on the emission layer EML, but the embodiment is not necessarily limited thereto. The electron transport region ETR may have a single layer made of a single material, a single layer made of different materials, or a multilayer structure made of different materials.

Referring to FIG. 8B, a light-emitting element OLED-1 according to an embodiment may include a first electrode AE, a functional layer FL-1, and a second electrode CE, wherein the functional layer FL-1 may include multiple light-emitting stacks OL1 and OL2. The light-emitting stacks OL1 and OL2 may each include an emission layer EML1 and EML2, respectively. Thus, the functional layer FL-1 may include multiple emission layers EML1 and EML2. For example, the light-emitting element OLED-1 according to an embodiment may be a tandem-type light-emitting element including multiple separated emission layers EML1 and EML2.

The light-emitting element OLED-1 may further include a charge generation layer CGL. When a voltage is applied to the light-emitting element OLED-1, the charge generation layer CGL may generate charges (electrons and holes) by creating complexes through redox (i.e., oxidation-reduction) reactions. The charge generation layer CGL may provide the generated charges to each of the adjacent light-emitting stacks OL1 and OL2. The charge generation layer CGL may increase the efficiency of current generated in each of the adjacent light-emitting stacks OL1 and OL2, and may also serve to balance charges between the adjacent light-emitting stacks OL1 and OL2.

The charge generation layer CGL may have a layer structure in which an n-type charge generation layer n-CGL and a p-type charge generation layer p-CGL are joined to each other.

The n-type charge generation layer n-CGL may be a charge generation layer that provides electrons to the adjacent light-emitting stacks OL1 and OL2. The n-type charge generation layer n-CGL may be a layer in which a base substrate is doped with an n-dopant. The p-type charge generation layer p-CGL may be a charge generation layer that provides holes to the adjacent light-emitting stacks OL1 and OL2. The p-type charge generation layer p-CGL may be a layer in which a base substrate is doped with a p-dopant.

The light emitting element OLED-1 may include a first light emitting stack OL1 and a second light emitting stack OL2 disposed on the first light emitting stack OL1. A charge generation layer CGL may be disposed between the first light emitting stack OL1 and the second light emitting stack OL2.

The first light emitting stack OL1 may include a first hole transport region HTR1, a first emission layer EML1, and a first electron transport region ETR1, and the second light emitting stack OL2 may include a second hole transport region HTR2, a second emission layer EML2, and a second electron transport region ETR2.

The description of the hole transport region HTR with reference to FIG. 8A may equally apply to the first hole transport region HTR1 and the second hole transport region HTR2. In an embodiment of the light emitting element OLED-1, the first hole transport region HTR1 and the second hole transport region HTR2 may have a same structure and be made of a same material. However, the disclosure is not necessarily limited thereto, and the first hole transport region HTR1 and the second hole transport region HTR2 may have different laminated structures or may be created to include different hole transport materials.

The description of the emission layer EML with reference to FIG. 8A may equally apply to the first emission layer EML1 and the second emission layer EML2. In an embodiment of the light emitting element OLED-1, the first emission layer EML1 and the second emission layer EML2 may have a same structure and be made of a same material. However, the disclosure is not necessarily limited thereto, and the first emission layer EML1 and the second emission layer EML2 may have different laminated structures or may be created to include different emission materials. Each of the first emission layer EML1 and the second emission layer EML2 may further include multiple laminated sub-emission layers or auxiliary emission layers.

Each of the first emission layer EML1 and the second emission layer EML2 may be patterned in an opening OP defined in a pixel defining layer PDL, as shown in FIG. 7. The first emission layer EML1 may include a first red emission layer EML-R1 overlapping a first pixel region PXA-R, a first green emission layer EML-G1 overlapping a second pixel region PXA-G, and a first blue emission layer EML-B1 overlapping a third pixel region PXA-B. The second emission layer EML2 may include a second red emission layer EML-R2 overlapping the first pixel region PXA-R, a second green emission layer EML-G2 overlapping the second pixel region PXA-G, and a second blue emission layer EML-B2 overlapping the third pixel region PXA-B. However, the disclosure is not necessarily limited thereto. If desirable, each of the first emission layer EML1 and the second emission layer EML2 may be commonly provided across the first to third pixel regions PXA-R, PXA-G, and PXA-B and a non-pixel region NPXA to substantially constitute a single structure.

The description of the electron transport region ETR with reference to FIG. 8A may equally apply to the first electron transport region ETR1 and the second electron transport region ETR2. In an embodiment of the light emitting element OLED-1, the first electron transport region ETR1 and the second electron transport region ETR2 may have a same structure and be made of a same material.

However, the disclosure is not necessarily limited thereto, and the first electron transport region ETR1 and the second electron transport region ETR2 may have different laminated structures or may be created to include different electron transport materials.

Although FIG. 8B illustrates that the first hole transport region HTR1, the second hole transport region HTR2, the first electron transport region ETR1, and the second electron transport region ETR2 are commonly provided across the first to third pixel regions PXA-R, PXA-G, and PXA-B and the non-pixel region NPXA to substantially constitute a single structure, the disclosure is not necessarily limited thereto. If desirable, a portion or all of the first hole transport region HTR1, the second hole transport region HTR2, the first electron transport region ETR1, and the second electron transport region ETR2 may be patterned in the opening OP defined in the pixel defining layer PDL, as shown in FIG. 7.

FIG. 9A is an enlarged plan view illustrating a portion of the display panel according to an embodiment of the disclosure. FIG. 9B is an enlarged plan view illustrating a portion of the display panel according to an embodiment of the disclosure; FIG. 9A illustrates an enlarged view of the arrangement of multiple pixels shown in FIG. 6 and the arrangement of metal lines ML defined adjacent thereto. FIG. 9B illustrates plan view of an embodiment based on the same plane shown in FIG. 9A.

Referring to FIGS. 9A and 9B, a metal line ML may be disposed in a non-pixel area NPXA that surrounds each of the pixel areas PXA-R, PXA-G, and PXA-B. In the specification, the metal line ML may be referred to as a "low-resistance layer”.

The metal line ML may include multiple first metal lines ML1 and multiple second metal lines ML2. The first and second metal lines ML1 and ML2 may be connected to each other to form a single, uninterrupted structure. Each first metal line ML1 may extend in a first direction DR1. The first metal lines ML1 may be arranged in a second direction DR2, and one of the pixel areas PXA-R, PXA-G, and PXA-B may be disposed between adjacent lines. Each second metal line ML2 may extend in the second direction DR2. The second metal lines ML2 may be arranged in a first direction DR1, and one of the pixel areas PXA-R, PXA-G, and PXA-B may be disposed between adjacent lines.

The metal line ML may have a shape that substantially surrounds the pixel areas PXA-R, PXA-G, and PXA-B. Although FIGS. 9A and 9B illustrate shapes in which the metal line ML extends in the first direction DR1 or the second direction DR2, the metal line ML may have a shape extending in another direction depending on the arrangement of the pixel areas PXA-R, PXA-G, and PXA-B.

Multiple metal openings OPM may be defined by the metal line ML. The metal openings OPM may include first to third openings OPM1, OPM2, and OPM3. The first to third openings OPM1, OPM2, and OPM3 may have surface areas different from each other, in plan view. For example, the surface area of the third opening OPM3 may be the largest in the first to third openings OPM1, OPM2, and OPM3, and the surface area of the first opening OPM1 may be the smallest in the first to third openings OPM1, OPM2, and OPM3. The regions in which the first to third openings OPM1, OPM2, and OPM3 are defined may be regions overlapping the first to third pixel areas PXA-R, PXA-G, and PXA-B, respectively. Each surface area of the first to third openings OPM1, OPM2, and OPM3 in plan view may be greater than each surface area of the first to third pixel areas PXA-R, PXA-G, and PXA-B in plan view.

A cutting part CC connecting two adjacent metal openings OPM among the metal openings OPM may be defined in the metal line ML. The cutting part CC may include a first cutting part CC1 defined in the first metal line ML1 and a second cutting part CC2 defined in the second metal line ML2. The first cutting part CC1 may connect two metal openings OPM adjacent to each other in the second direction DR2 among the metal openings OPM. The first cutting part CC1 may refer to a portion in which the first metal line ML1 is cut (or ‘removed’) in the first direction DR1. The first cutting part CC1 may refer to a portion in which the first metal line ML1 is substantially not disposed. The second cutting part CC2 may connect two metal openings OPM adjacent to each other in the first direction DR1 among the metal openings OPM. The second cutting part CC2 may refer to a portion in which the second metal line ML2 is cut (or ‘removed’) in the second direction DR2. The second cutting part CC2 may refer to a portion in which the second metal line ML2 is substantially not disposed.

Unlike what is illustrated in FIGS. 9A and 9B, the cutting part CC may be defined at any position that connects two adjacent metal openings OPM among the metal openings OPM. As described below, since the display panel according to an embodiment of the disclosure includes the metal line ML, the second electrodes CE1 and CE2 (see FIG. 10A) between pixels may be disconnected in the non-pixel area NPXA. However, due to the presence of the cutting part CC, that is, the area in which the metal line ML is not disposed, the disconnection of the second electrodes CE1 and CE2 (see FIG. 10B) between the pixels may be prevented. Provided that the second electrodes CE1 and CE2 (see FIG. 10B) between the pixels are electrically connected, the cutting part CC may be defined at any position of the metal line ML.

FIGS. 10A and 10B are enlarged cross-sectional views illustrating portions of a display panel according to an embodiment of the disclosure. In FIG. 10A, a cross-sectional view taken along the section line II-II' shown in FIG. 9A is illustrated. In FIG. 10B, a cross-sectional view taken along the section line III-III' shown in FIG. 9A is illustrated. In FIGS. 10A and 10B, a portion of the components of the display panel is illustrated for convenience of explanation. In FIGS. 10A and 10B, in the pixels included in the display panel of an embodiment, light emitting elements OLED1 and OLED2 and metal line ML, which overlap the first pixel area PXA-R, the second pixel area PXA-G, and the non-pixel area NPXA defined therebetween, respectively, are illustrated as an example; however, the following description may be applied to any other arbitrary adjacent pixel areas. To the extent that an element is not described in detail with respect to FIGS. 10A and 10B, it may be understood that the element is at least similar to a corresponding element that has been previously described in FIGS. 4A to 9B.

Referring to FIGS. 10A and 10B, the display panel of an embodiment may include a base layer BL and a circuit element layer DP-CL disposed on the base layer BL, and a pixel defining layer PDL, light emitting elements OLED1 and OLED2, and a metal line ML disposed on the circuit element layer DP-CL.

The light emitting elements OLED1 and OLED2 may include a first light emitting element OLED1 and a second light emitting element OLED2, which are adjacent to each other in a first direction DR1. The first light emitting element OLED1 may correspond to the first pixel area PXA-R. The first light emitting element OLED1 may have a structure in which a (1-1)-th electrode AE1, a first functional layer FL1, and a (2-1)-th electrode CE1 are sequentially layered. The second light emitting element OLED2 may correspond to the second pixel area PXA-G. The second light emitting element OLED2 may have a structure in which a (1-2)-th electrode AE2, a second functional layer FL2, and a (2-2)-th electrode CE2 are sequentially layered.

The metal line ML may be disposed overlapping the non-pixel area NPXA. The metal line ML may be disposed between the first pixel area PXA-R and the second pixel area PXA-G. The metal line ML may be disposed on the pixel defining layer PDL. The metal line ML may be disposed (e.g., “directly disposed”) on the pixel defining layer PDL. The metal line ML may be disposed on a portion of a top surface of the pixel defining layer PDL, and might not be disposed on side surfaces of the pixel defining layer PDL or in the pixel opening OP. The metal line ML may include aluminum, titanium, or both. For example, the metal line ML may include a single layer of aluminum, or may include a multilayer structure of aluminum/titanium/aluminum. The resistivity of the metal line ML may be smaller than the resistivity of the functional layers FL1 and FL2.

A metal opening OPM may be defined in the metal line ML. A pixel opening OP may be defined in the pixel defining layer PDL, and the metal opening OPM may be defined to correspond to the pixel opening OP. The metal opening OPM may be defined to have a larger surface area in plan view than the pixel opening OP. A portion of the functional layers FL1 and FL2 may be disposed in the metal opening OPM.

Residue RT1 and RT2 may be disposed on a top surface of the metal line ML. The functional layers FL1 and FL2 and the second electrodes CE1 and CE2 may be disposed in the metal opening OPM, and the residue RT1 and RT2 may be disposed on the metal line ML. The residue RT1 and RT2 may be residue generated during the formation of the light emitting elements OLED1 and OLED2, and may include the same material as that included in the functional layers FL1 and FL2 and the second electrodes CE1 and CE2. However, in an embodiment, the residue RT1 and RT2 may be omitted.

The non-pixel area NPXA may include a first area A1 on which the metal line ML is disposed. At least a portion of the second electrodes CE1 and CE2 overlapping the first area A1 may be disconnected. A portion of the (2-1)-th electrode CE1 of the first light emitting element OLED1 may be spaced apart from a portion of the (2-2)-th electrode CE2 of the second light emitting element OLED2, and the metal line ML may be disposed between the spaced apart portions. A portion of the first functional layer FL1 of the first light emitting element OLED1 may be spaced apart from a portion of the second functional layer FL2 of the second light emitting element OLED2, and the metal line ML may be disposed between the spaced apart portions.

The metal line ML may include a bottom surface in contact with the pixel defining layer PDL, a top surface opposite to the bottom surface in a thickness direction DR3, and side surfaces surrounding the bottom and top surfaces. The side surfaces of the metal line ML might not be in contact with the second electrodes CE1 and CE2 of the light emitting elements OLED1 and OLED2. The side surfaces of the metal line ML may be in contact with the functional layers FL1 and FL2 of the light emitting elements OLED1 and OLED2.

In the display panel according to an embodiment, the metal line ML may be disposed in the non-pixel area NPXA to prevent side effects caused by lateral leakage current between adjacent pixels. In the disclosure, the term “lateral leakage current” refers to current flowing in a direction other than the third direction DR3, which is the laminated direction of the light emitting elements and the direction in which an image is displayed. The lateral leakage current may refer to current flowing in a direction parallel to the plane defined by the first direction DR1 and the second direction DR2. Since the display panel according to an embodiment includes a bypass path provided by the metal line ML, the lateral leakage current may flow toward the metal line ML rather than into adjacent pixels. Since the metal line ML has low resistivity and is disposed in the non-pixel area NPXA between adjacent pixels, it may serve as a bypass path for the lateral leakage current. Since the display panel according to an embodiment includes the metal line ML, the display panel may prevent color mixing and luminance degradation between adjacent pixel areas. For example, even when lateral leakage current is generated in the first functional layer FL1 of the first light emitting element OLED1, the current may flow to the metal line ML rather than to the adjacent second light emitting element OLED2, thereby ensuring device reliability.

The non-pixel area NPXA may include a second area A2 in which a cutting part CC (see FIG. 9A) is defined. In other words, the non-pixel area NPXA may include the second area A2 in which the metal line ML is not disposed. The second electrodes CE1 and CE2 overlapping the second area A2 may be electrically connected due to the absence of the metal line ML. The (2-1)-th electrode CE1 of the first light emitting element OLED1 and the (2-2)-th electrode CE2 of the second light emitting element OLED2 may be electrically connected in the second area A2 on which the metal line ML is not disposed.

In conventional display panels, techniques such as placing certain components in the non-pixel area have been applied to prevent lateral leakage current. However, such approaches may cause side effects such as electrical disconnection of the second electrode in the light emitting element or an increase in the contact resistance of the electrode. In contrast, the display panel according to an embodiment of the disclosure may ensure a reliable electrical path for the second electrodes CE1 and CE2 by defining a cutting part CC (see FIG. 9A) in the metal line ML, thereby ensuring stable device operation.

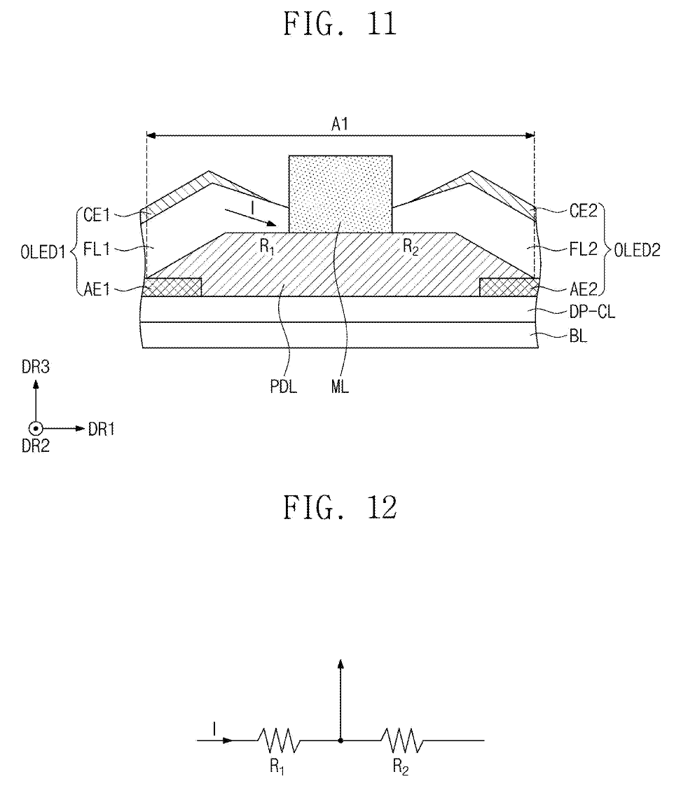

FIG. 11 is an enlarged cross-sectional view illustrating a portion of a display panel according to an embodiment of the disclosure. FIG. 11 illustrates an enlarged view of a portion of the display panel structure in the area A1 shown in FIG. 10A. FIG. 12 is a circuit diagram of a partial area of the display panel according to an embodiment of the disclosure. FIG. 12 is a simplified circuit diagram illustrating the flow of lateral leakage current between the light emitting element and the metal line in the area A1 shown in FIG. 10A. Hereinafter, the effects of the disclosure will be described with reference to FIGS. 11 and 12.

In the first area A1, a lateral leakage current I generated by the first light emitting element OLED1 may flow along the metal line ML. In the first area A1, the resistance of the metal line ML may be extremely small compared to the resistance R2 of the second light emitting element OLED2. Accordingly, the lateral leakage current I generated by the first light emitting element OLED1 may flow into the metal line ML rather than into the direction of the second light emitting element OLED2. Since the metal line ML having a low resistivity is disposed in the first area A1 and serves as a bypass path for the lateral leakage current, color mixing between adjacent pixel areas may be prevented, and brightness degradation may be avoided.

The display panel according to an embodiment of the disclosure and the electronic apparatus including the same may improve reliability by including a metal line in which a cutting part is defined, thereby reducing side effects caused by lateral leakage current and also reducing contact resistance between electrodes in the light emitting element. The display panel according to an embodiment of the disclosure and an electronic apparatus including the same may improve color purity and display quality by including a metal pattern overlapping the non-pixel area to divert lateral leakage current. The display panel and electronic apparatus including the same may ensure stable current conduction between electrodes in the light emitting element by defining a cutting part in the metal line, thereby solving the problem of electrode discontinuity and securing device driving reliability.

The display panel and the electronic apparatus including the same according to an embodiment of the disclosure may improve display quality by preventing color mixing between pixels through reduction of lateral leakage current between adjacent pixels by including the metal line.

The display panel and the electronic apparatus including the same according to an embodiment of the disclosure may secure driving reliability of elements and solving the problem of electrode discontinuity by defining a cutout portion in the metal line.

According to embodiments of the disclosure, there is provided a design for a display device and an electronic device that includes the same that reduces lateral leakage current and improves color purity and image quality in a display device where functional organic layers FL including the emission layers are deposited using an open mask as opposed to a pattern mask. Metal lines ML are included in non-pixel areas NPXA between pixels to draw lateral leakage current from entering into adjacent pixels, thereby reducing crosstalk between the pixels and resulting in improved color purity and improved image quality. The metal lines ML are formed to be non-continuous by including cutting (or removed) parts CC to allow portions of the cathode electrodes CE of neighboring pixels to still electrically connect to improve contact resistance. Thus a simpler manufacturing process and improved image quality can be simultaneously achieved.

Although the disclosure has been described with reference to the embodiments, it will be understood that various changes and modifications of the disclosure may be made by one ordinary skilled in the art or one having ordinary knowledge in the art without departing from the spirit and technical field of the disclosure as hereinafter claimed. Hence, the technical scope of the disclosure is to be determined by the following claims, and should not be limited by the foregoing description.

What is claimed is:

1. A display panel comprising:
a base layer on which a plurality of pixel areas and a non-pixel area surrounding the plurality of pixel areas are defined;
a circuit element layer disposed on the base layer; and
a display element layer disposed on the circuit element layer,
wherein the display element layer comprises:
a plurality of light-emitting elements, each having a first electrode, a functional layer, and a second electrode sequentially stacked on each other;
a pixel defining layer overlapping the non-pixel area and defining a plurality of pixel openings, the plurality of pixel openings are configured to expose at least a portion of a top surface of the first electrode and to respectively correspond to the plurality of pixel areas;
a metal line disposed on the pixel defining layer and defining a plurality of metal openings, the plurality of metal openings respectively overlap the plurality of pixel openings in plan view; and
a cutout portion configured to connect two adjacent metal openings of the plurality of metal openings.

2. The display panel of claim 1, wherein
the non-pixel area comprises a first area on which the metal line is disposed and a second area in which the cutout portion is defined,
at least a portion of the second electrode overlapping the first area is disconnected, and
the second electrode overlapping the second area is electrically connected.

3. The display panel of claim 1, wherein
the plurality of pixel areas comprise a first pixel area and a second pixel area adjacent to the first pixel area in a first direction, and
the metal line is disposed between the first pixel area and the second pixel area.

4. The display panel of claim 3, wherein
the metal line comprises:
a first metal line extending in the first direction; and
a second metal line extending in a second direction intersecting the first direction in plan view, and
the first metal line and the second metal line are connected to each other in a plan view to constitute a single, uninterrupted structure.

5. The display panel of claim 4, wherein
the cutout portion comprises:
a first cutout portion defined in the first metal line; and
a second cutout portion defined in the second metal line,
the first cutout portion is configured to connect two adjacent metal openings in the second direction to each other, and
the second cutout portion is configured to connect two adjacent metal openings in the first direction to each other.

6. The display panel of claim 3, wherein
the plurality of light-emitting elements comprise:
a first light-emitting element corresponding to the first pixel area and in which a (1-1)-th electrode, a first functional layer, and a (2-1)-th electrode sequentially stacked on each other; and
a second light-emitting element corresponding to the second pixel area and in which a (1-2)-th electrode, a second functional layer, and a (2-2)-th electrode sequentially stacked on each other, and
a portion of the first functional layer and a portion of the second functional layer are spaced apart from each other in the first direction with the metal line disposed between the portion of the first functional layer and the portion of the second functional layer.

7. The display panel of claim 6, wherein a portion of the (2-1)-th electrode and a portion of the (2-2)-th electrode are spaced apart from each other in the first direction with the metal line disposed between the portion of the (2-1)-th electrode and the portion of the (2-2)-th electrode.

8. The display panel of claim 1, wherein a surface area of each of the plurality of metal openings in plan view is greater than a surface area of each of the pixel openings in plan view.

9. The display panel of claim 1, wherein the metal line is disposed directly on the pixel defining layer.

10. The display panel of claim 9, wherein the metal line is disposed on a portion of a top surface of the pixel defining layer in plan view.

11. The display panel of claim 1, wherein
the metal line comprises:
a bottom surface in contact with the pixel defining layer;
a top surface facing the bottom surface in a thickness direction; and
a side surface surrounding the bottom surface and the top surface, and
the side surface is in contact with the functional layer.

12. The display panel of claim 11, wherein the side surface and the second electrode may be spaced apart from each other in plan view.

13. The display panel of claim 1, wherein the functional layer comprises:
a first light-emitting stack comprising a first hole transport region, a first emission layer disposed on the first hole transport region, and a first electron transport region disposed on the first emission layer;
a charge generation layer disposed on the first light-emitting stack; and
a second light-emitting stack comprising a second hole transport region, a second emission layer disposed on the second hole transport region, and a second electron transport region disposed on the second emission layer.

14. A display panel comprising:
a base layer in which a plurality of pixel areas and a non-pixel area surrounding the plurality of pixel areas are defined;
a circuit element layer disposed on the base layer; and
a display element layer disposed on the circuit element layer,
wherein the display element layer comprises:
a plurality of light-emitting elements, each having a first electrode, a functional layer, and a second electrode sequentially stacked on each other;
a pixel defining layer overlapping the non-pixel area and defining a plurality of pixel openings, the plurality of pixel openings are configured to expose at least a portion of a top surface of the first electrode and to respectively correspond to the plurality of pixel areas in plan view; and
a low-resistance layer overlapping the non-pixel area and disposed on the pixel defining layer,
wherein a side surface of the low-resistance layer and the second electrode are spaced apart from each other in plan view.

15. The display panel of claim 14, wherein the low-resistance layer comprises aluminum or titanium.

16. The display panel of claim 14, further comprising an encapsulation layer disposed on the display element layer.

17. An electronic device configured to provide an image, the electronic device comprising:
a display module comprising a display panel in which a plurality of pixel areas and a non-pixel area surrounding the plurality of pixel areas are defined; and
a power module electrically connected to the display module,
wherein the display panel comprises:
a plurality of light-emitting elements, each having a first electrode, a functional layer, and a second electrode, which are sequentially stacked on each other;
a pixel defining layer overlapping the non-pixel area and defining a plurality of pixel openings, the plurality of pixel openings are configured to expose at least a portion of a top surface of the first electrode and to respectively correspond to the plurality of pixel areas in plan view;
a metal line disposed on the pixel defining layer and defining a plurality of metal openings, the plurality of metal openings respectively overlap the plurality of pixel openings in plan view; and
a cutout portion configured to connect two adjacent metal openings of the plurality of metal openings.

18. The electronic device of claim 17, wherein
the plurality of pixel areas comprise a first pixel area and a second pixel area adjacent to the first pixel area in a first direction, and
the plurality of light-emitting elements comprise:
a first light-emitting element corresponding to the first pixel area and in which a (1-1)-th electrode, a first functional layer, and a (2-1)-th electrode are sequentially stacked on each other; and
a second light-emitting element corresponding to the second pixel area and in which a (1-2)-th electrode, a second functional layer, and a (2-2)-th electrode are sequentially stacked on each other.

19. The electronic device of claim 18, wherein
a portion of the first functional layer and a portion of the second functional layer are spaced apart from each other in the first direction with the metal line disposed between the portion of the first functional layer and the portion of the second functional layer, and
a portion of the (2-1)-th electrode and a portion of the (2-2)-th electrode are spaced apart from each other in the first direction with the metal line disposed between the portion of the (2-1)-th electrode and the portion of the (2-2)-th electrode.

20. The electronic device of claim 18, wherein
the metal line comprises a first metal line extending in the first direction and a second metal line extending in a second direction intersecting the first direction in plan view,
the cutout portion comprises a first cutout portion defined in the first metal line and a second cutout portion defined in the second metal line,
the first cutout portion is configured to connect two adjacent metal openings in the second direction to each other, and
the second cutout portion is configured to connect two adjacent metal openings in the first direction to each other.
